(19) United States
(12) Patent Application Publication
(10) Pub. No.: US 2025/0255162 A1
(43) Pub. Date: Aug. 7, 2025

(54) Organic Light Emitting Display Device

(71) Applicant: LG Display Co., Ltd., Seoul (KR)

(72) Inventors: GyuHo Lee, Paju-si (KR); Suk Choi, Paju-si (KR); Sungjin Park, Paju-si (KR)

(21) Appl. No.: 18/945,039

(22) Filed: Nov. 12, 2024

(30) Foreign Application Priority Data
Feb. 6, 2024 (KR) 10-2024-0018259

(51) Int. Cl. H10K 59/80; H10K 59/122

(52) U.S. Cl. CPC H10K 59/8792; H10K 59/122

(57) ABSTRACT

Disclosed is an organic light emitting display device comprising a substrate, a first light emitting area disposed on the substrate and emitting a first color and a second light emitting area disposed on the substrate and emitting a second color different from the first color, a first color filter disposed on the first light emitting area, a second color filter disposed on the second light emitting area, and a black matrix disposed to be in contact with at least one of an upper surface of the first color filter and an upper surface of the second color filter, wherein the black matrix includes scattering particles.

### CROSS-REFERENCE TO RELATED APPLICATION

This application claims the benefit of the Republic of Korea Patent Application No. 10-2024-0018259 filed on Feb. 6, 2024, which is hereby incorporated by reference in its entirety.

### BACKGROUND

### Technical Field

The present disclosure relates to an organic light emitting display device.

### Description of the Related Art

As an information society develops, demands for a display device for displaying an image are increasing in various forms. Accordingly, various display devices such as a liquid crystal display (LCD), a plasma display (PDP), and an organic light emitting display (OLED) have recently been used.

Among the display devices, the organic light emitting display device is a self-emission type and has excellent viewing angle and contrast ratio compared to the liquid crystal display (LCD). In addition, since a separate backlight is not required, light weight and thinness are possible, and power consumption is advantageous. Furthermore, the organic light emitting display device has advantages of being able to drive a DC low voltage, a fast response speed, and particularly low manufacturing cost.

An organic light emitting display device has a structure in which an organic light emitting element including a light emitting layer is provided between a cathode for injecting electrons and an anode for injecting holes. An organic light emitting display device is a display device using the principle that when electrons generated from a cathode and holes generated from an anode are injected into an emission layer, the injected electrons and holes are combined to generate excitons, and the generated excitons fall from an excited state to a ground state and emit light.

Light introduced from the outside of the display device is reflected by electrodes and wires provided inside the display device to form reflected light, and as the reflected light is emitted through the light exit surface of the display device, it may be visually recognized as a mura pattern, for example, a rainbow mura or a ring mura. In this case, there is a problem that it is difficult to realize real black due to a mura pattern formed by reflecting external light by electrodes and wirings provided inside the display device, or it makes the user's eyes tired.

### SUMMARY

The present disclosure has been made in view of the above problems, and it is an object of the present disclosure to provide an organic light emitting display device in which a portion of the black matrix that divides the color filter covers a portion of the upper surface of the color filter, and light scattering particles are included inside the black matrix, so that no mura pattern is formed by external light reflected by electrodes and wiring provided inside the display device.

In accordance with an embodiment of the present disclosure, the above and other objects can be accomplished by the provision of an organic light emitting display device comprising a substrate, a first light emitting area disposed on the substrate and emitting a first color and a second light emitting area disposed on the substrate and emitting a second color different from the first color, a first color filter disposed on the first light emitting area, a second color filter disposed on the second light emitting area, and a black matrix disposed to be in contact with at least one of an upper surface of the first color filter and an upper surface of the second color filter, wherein the black matrix includes scattering particles.

And the above and other objects can be accomplished by the provision of an organic light emitting display device comprising a substrate including a first light emitting area and a second light emitting area, a first color filter disposed on the first light emitting area, a second color filter disposed on the second light emitting area, and a black matrix disposed on the first color filter and the second color filter, wherein the black matrix includes a first opening corresponding to the first light emitting area and a second opening corresponding to the second light emitting area, and the black matrix includes scattering particles.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of an organic light emitting display device according to an embodiment of the present disclosure.

FIG. 2 is a schematic plan view of an organic light emitting display device according to an embodiment of the present disclosure.

FIG. 3 is a plan view illustrating an example of pixels included in an organic light emitting display device according to an embodiment of the present disclosure.

FIG. 4 is a cross-sectional view of pixels included in an organic light emitting display device along cross-sectional I-I′ of FIG. 3 according to an embodiment of the present disclosure.

FIG. 5 is an enlarged view of area a of FIG. 4 that illustrates a first pixel included in an organic light emitting display device according to an embodiment of the present disclosure.

FIG. 6 is a cross-sectional view of pixels included in an organic light emitting display device along cross-sectional I-I′ of FIG. 3 according to another embodiment of the present disclosure.

FIG. 7 is an enlarged view of area b of FIG. 6 that illustrates a first pixel included in an organic light emitting display device according to another embodiment of the present disclosure.

FIG. 8 is a plan view illustrating an example of pixels included in an organic light emitting display device according to another embodiment of the present disclosure.

FIG. 9 is a cross-sectional view of pixels included in an organic light emitting display device along cross-sectional II-II′ of FIG. 8 according to another embodiment of the present disclosure.

FIG. 10 is a cross-sectional view of pixels included in an organic light emitting display device along cross-sectional II-II′ of FIG. 8 according to another embodiment of the present disclosure.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

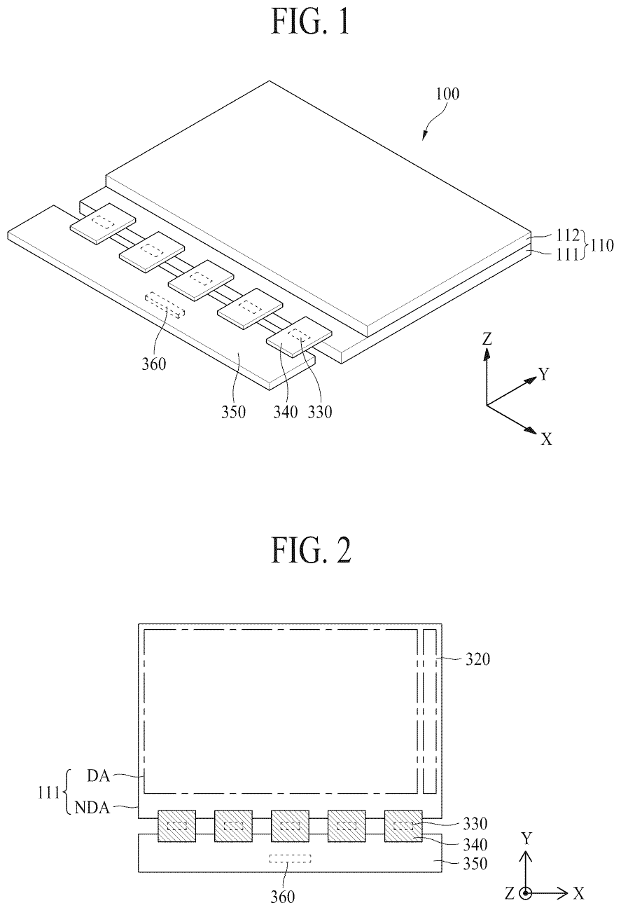

FIG. 1 is a perspective view illustrating a display device according to an embodiment of the present disclosure. FIG. 2 is a plan view illustrating a first substrate, a gate driver, a source drive IC, a flexible film, a circuit board, and a timing controller of FIG. 1 according to an embodiment of the present disclosure. In each figure including FIGS. 1 and 2, directions are schematically shown by a XYZ coordinate system consisted of X, Y, and Z axes. Hereinafter, it has been described that the display device according to an embodiment of the present disclosure is an organic light emitting display, but the present disclosure is not limited thereto. That is, the display device according to an embodiment of the present disclosure may be implemented as one of a liquid crystal display, a field emission display, and an electrophoretic display as well as an organic light emitting display.

Referring to FIGS. 1 and 2, a display device 100 according to an embodiment of the present disclosure includes a display panel 110, a gate driver 320, a source drive integrated circuit (hereinafter referred to as “IC”) 330, a flexible film 340, a circuit board 350, and a timing controller 360.

The display panel 110 includes a first substrate 111 and a second substrate 112. The second substrate 112 may be an encapsulation substrate. The first substrate 111 may be a plastic film or a glass substrate. The second substrate 112 may be a plastic film, a glass substrate, or an encapsulation film.

Gate lines, data lines, and pixels are formed on one surface of the first substrate 111 facing the second substrate 112. The pixels are provided in a region defined by an intersection structure of gate lines and data lines.

Each of the pixels may include a thin film transistor and an organic light emitting element including a first electrode, an organic emission layer, and a second electrode. Each of the pixels supplies a predetermined current to the organic light emitting element according to the data voltage of the data line when a gate signal is input from a gate line using a thin film transistor. Accordingly, the organic light emitting element of each of the pixels can emit light with a predetermined brightness according to a predetermined current.

The display panel 110 including the first substrate 111 and the second substrate 112 therein may be divided into a display area DA in which pixels are formed to display an image and a non-display area NDA in which an image is not displayed. Gate lines, data lines, and pixels may be formed in the display area DA. A gate driver 320 and pads may be formed in the non-display area NDA.

The gate driver 320 supplies gate signals to gate lines according to a gate control signal input from the timing controller 360. The gate driver 320 may be formed in a gate driver in panel (GIP) manner in the non-display area NDA provided outside one or both sides of the display area DA of the display panel 110. Alternatively, the gate driver 320 may be manufactured as a driving chip, mounted on a flexible film, and attached to the non-display area NDA outside one or both sides of the display area DA of the display panel 110 in a tape automated bonding (TAB) method.

The source drive IC 330 receives digital video data and a source control signal from the timing controller 360. The source drive IC 330 converts digital video data into analog data voltages according to a source control signal and supplies the converted analog data voltages to the data lines. When the source drive IC 330 is manufactured as a driving chip, it may be mounted on the flexible film 340 in a chip-on-film (COF) or chip-on-plastic (COP) manner.

Pads such as data pads may be formed in the non-display area NDA of the display panel 110. Wirings connecting the pads to the source drive IC 330 and wirings connecting the pads to the circuit board 350 may be formed in the flexible film 340. The flexible film 340 is attached onto the pads using an anisotropic conducting film, and thus the wirings of the pads and the flexible film 340 may be connected to each other.

The circuit board 350 may be attached to the flexible films 340. A plurality of circuits implemented with driving chips may be mounted on the circuit board 350. For example, the timing controller 360 may be mounted on the circuit board 350. The circuit board 350 may be a printed circuit board or a flexible printed circuit board.

The timing controller 360 receives digital video data and a timing signal from an external system board through a cable of the circuit board 350. The timing controller 360 generates a gate control signal for controlling the operation timing of the gate driver 320 and a source control signal for controlling the source drive ICs 330 based on the timing signal. The timing controller 360 supplies the gate control signal to the gate driver 320 and supplies the source control signal to the source drive ICs 330.

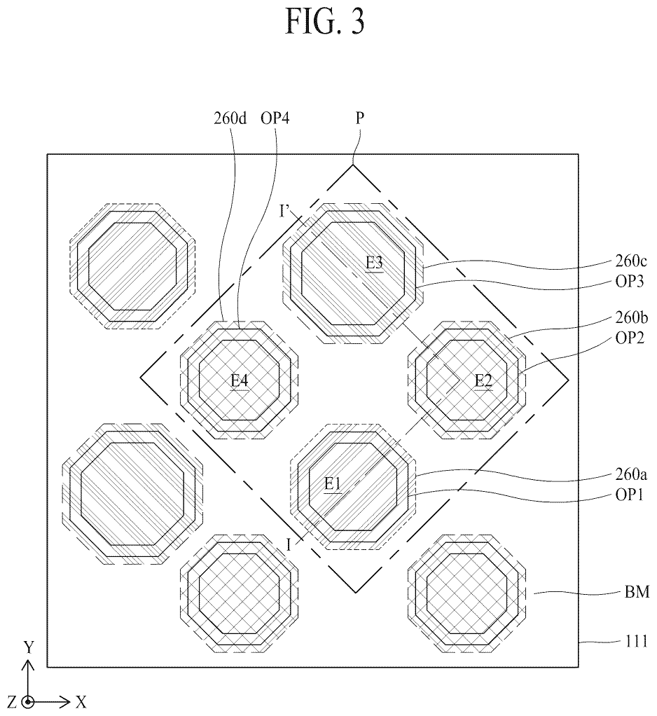

FIG. 3 is a plan view illustrating an example of pixels included in an organic light emitting display device according to an embodiment of the present disclosure.

As shown in FIG. 3, the organic light emitting display device according to an embodiment of the present disclosure includes a plurality of pixels P, a color filter 260, and a black matrix BM having an opening OP.

Any one of the plurality of pixels P includes a plurality of light emitting areas E1, E2, E3, and E4.

The plurality of light emitting areas E1, E2, E3, and E4 may include the first light emitting area E1, the second light emitting area E2, the third light emitting area E3, and the fourth light emitting area E4, and each of the plurality of light emitting areas E1, E2, E3, and E4 may emit light of any one of red (R), green (G), or blue (B). The first light emitting area E1 may emit red (R) light, for example, and the second light emitting area E2 and the fourth light emitting area E4 may emit green (G) light, for example, and the third light emitting area E3 may emit blue (B) light, for example. Meanwhile, the color of light emitted by each of the light emitting areas E1, E2, E3, and E4 is not limited thereto, and in some cases, white (W) light may be emitted, and various colors of light may be emitted according to the level of those skilled in the art.

A plurality of light emitting areas E1, E2, E3, and E4 may be formed to have different sizes. For example, the third light emitting area E3 may be larger than the first light emitting area E1, the second light emitting area E2, and the fourth light emitting area E4, the first light emitting area E1 may be larger than the second light emitting area E2 and the fourth light emitting area E4, and the second light emitting area E2 and the fourth light emitting area E4 may be formed to have the same size. However, the present disclosure is not limited thereto, and the first light emitting area E1 to the fourth light emitting area E4 may be formed in various sizes and various arrangements depending on a level of the art.

Color filters 260a, 260b, 260c, and 260d and a black matrix BM may be formed on the plurality of pixels P, and a plurality of openings OP1, OP2, OP3, and OP4 may be formed in the black matrix BM.

The color filters 260a, 260b, 260c, and 260d include a first color filter 260a, a second color filter 260b, a third color filter 260c, and a fourth color filter 260d. The color filters 260a, 260b, 260c, and 260d may transmit light of the same wavelength band as the color of the light emitted from the light emitting areas E1, E2, E3, and E4, respectively. For example, the first color filter 260a is provided to correspond to the first light emitting area E1, may transmit red (R) light, the second color filter 260b and the fourth color filter 260d are provided to correspond to the second light emitting area E2 and the fourth light emitting area E4, respectively, may transmit green (G) light, and the third color filter 260c is provided to correspond to the third light emitting area E3, and may transmit blue (B) light.

The color filters 260a, 260b, 260c, and 260d may be formed in the same shape as the light emitting areas E1, E2, E3, and E4, and the color filters 260a, 260b, 260c, and 260d are formed to be spaced apart from each other.

A plurality of light emitting areas E1, E2, E3, and E4, color filters 260a, 260b, 260c, and 260d, and a plurality of openings OP1, OP2, OP3, and OP4 of the black matrix BM may correspond to each other. For example, the first light emitting area E1 may correspond to the first color filter 260a and the first opening OP1 of the black matrix BM, the second light emitting area E2 may correspond to the second color filter 260b and the second opening OP2 of the black matrix BM, the third light emitting area E3 may correspond to the third color filter 260c and the third opening OP3 of the black matrix BM, and the fourth light emitting area E4 may correspond to the fourth color filter 260d and the fourth opening OP4 of the black matrix BM.

According to an embodiment of the present disclosure, each of the light emitting areas E1, E2, E3, and E4 may be provided in any one shape of an n-gon (n is an integer greater than or equal to 6), a circle, and an ellipse. For example, as illustrated in FIG. 3, each of the light emitting areas E1, E2, E3, and E4 may be provided in an octagon shape. Also, the color filters 260a, 260b, 260c, and 260d corresponding to each of the light emitting areas E1, E2, E3, and E4 and the openings OP1, OP2, OP3, and OP4 of the black matrix BM may be provided in any one of an n-gon (n is an integer greater than or equal to 6), a circle, and an ellipse. For example, the first light emitting area E1 may be provided in an octagon, and the first color filter 260a corresponding to the first light emitting area E1 and the first opening OP1 of the black matrix BM may be provided in an octagon.

When the first light emitting area E1, the first color filter 260a, and the first opening OP1 of the black matrix BM are formed in an octagon, for example, the first light emitting area E1, the first color filter 260a, and the first opening OP1 of the black matrix BM may be formed in an octagon including a first side and a second side, respectively. In this case, a first side of the first light emitting area E1 may be formed to face a first side of the first color filter 260a and a first opening OP1 of the black matrix BM, and a second side of the first light emitting area E1 may be formed to face a second side of the first color filter 260a and a second side of the first opening OP1 of the black matrix BM.

The first side and the second side of the first light emitting area E1 may be spaced apart from the first side and the second side of the first opening OP1 of the black matrix BM by the same length, respectively. More specifically, the shortest distance between the first side of the first light emitting area E1 and the first side of the first opening OP1 of the black matrix BM may be provided to be the same as the shortest distance between the second side of the first light emitting area E1 and the second side of the first opening OP1 of the black matrix BM.

According to an embodiment of the present disclosure, the first light emitting area E1, the first color filter 260a, and the first opening OP1 of the black matrix BM are formed in any one shape of an n-gon (n is an integer of 6 or more), a circle, and an ellipse, and the first light emitting area E1 and the first opening OP1 of the black matrix BM are formed to be spaced apart from each side by a predetermined distance. Therefore, even if external light is irradiated to the organic light emitting display device according to an embodiment of the present disclosure and reflected by internal electrodes and wires, a mura pattern, for example, a rainbow mura or a ring mura, is prevented from being formed, thereby improving the visibility of a user.

Meanwhile, for convenience of description, the first light emitting area E1, the first color filter 260a, and the first opening OP1 have been mainly described in FIG. 3, but the second to fourth light emitting areas E2 to E4, the second to fourth color filters 260b to 260d, and the second to fourth openings OP2 to OP4 of the black matrix may have the same contents as those of the first color filter 260a and the first opening OP1 of the black matrix BM, which correspond to the first light emitting area E1 described above.

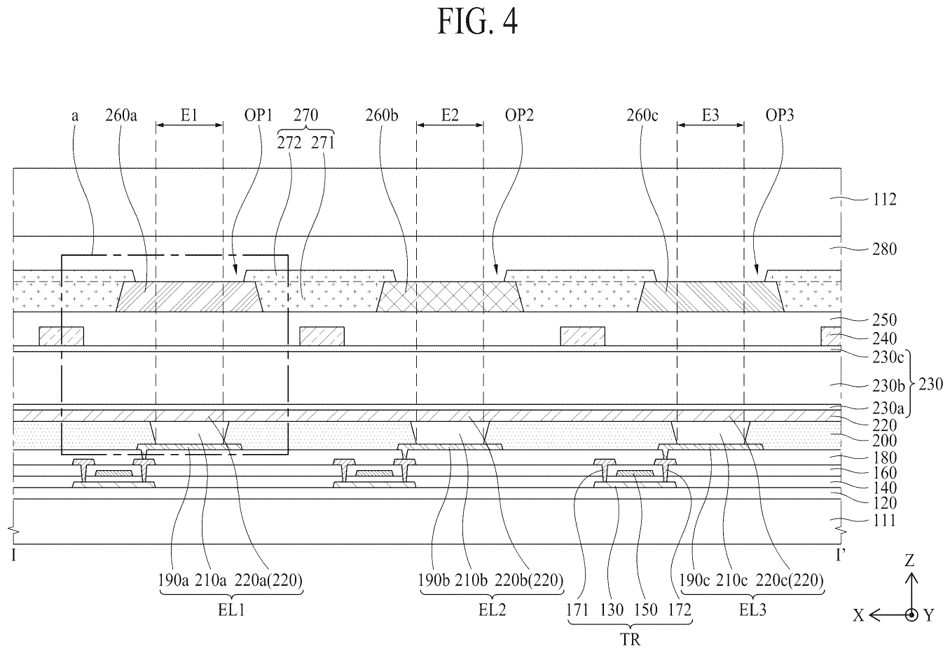

FIG. 4 is a cross-sectional view of pixels included in an organic light emitting display device according to an embodiment of the present disclosure. In this case, FIG. 4 corresponds to the cross-sectional I-I′ of FIG. 3.

As shown in FIG. 4, the organic light emitting display device according to an embodiment of the present disclosure includes a first substrate 111, a buffer layer 120, an active layer 130, a gate insulating layer 140, a gate electrode 150, an interlayer insulating layer 160, a source electrode 171, a drain electrode 172, a planarization layer 180, a first electrode 190a, 190b, and 190c, a bank 200, an organic light emitting layer 210a, 210b, and 210c, a second electrode 220a, 220b and 220c, an encapsulation layer 230, a touch electrode 240, a touch insulating layer 250, color filters 260a, 260b, and 260c, a black matrix 270, an overcoating layer 280, and a second substrate 112.

The first substrate 111 may be made of glass or plastic. In particular, the first substrate 111 may be made of transparent plastic having flexible characteristics, for example, polyimide. When the polyimide is used as the first substrate 111, considering that a high-temperature deposition process is performed on the first substrate 111, heat-resistant polyimide capable of withstanding high temperature may be used.

The buffer layer 120 may be formed on the first substrate 111. The buffer layer 120 may protect the active layer 130 by blocking air and moisture. The buffer layer 120 may be made of an inorganic insulating material such as silicon oxide, silicon nitride, or metal oxide, but is not limited thereto and may be made of an organic insulating material.

The thin film transistor TR may be formed on the buffer layer 120. The thin film transistor TR may include an active layer 130, a gate electrode 150, a source electrode 171, and a drain electrode 172. In this case, the thin film transistor TR may be a driving thin film transistor, but is not limited thereto.

The thin film transistor TR may be provided to correspond to each of the light emitting areas E1, E2, and E3 provided in each pixel, and Meanwhile, FIG. 4 describes that only one thin film transistor TR is formed in each of the light emitting areas E1, E2, and E3, but the present disclosure is not limited thereto, and various numbers of thin film transistors may be provided to correspond to the light emitting area according to the technology level of those skilled in the art.

The active layer 130 may be formed on the buffer layer 120. The active layer 130 may include any one of a semiconductor material, for example, amorphous silicon, polycrystalline silicon, and oxide semiconductor material.

Although not specifically shown, the active layer 130 includes a channel portion, a first connection portion provided on one side of the channel portion, for example, on the left side, and a second connection portion provided on another side of the channel portion, for example, on the right side. The channel portion overlaps the gate electrode 150. By forming in this way, in the conductive process of making the portion of the active layer 130 a conductor, the channel portion is protected by the gate electrode 150 so that semiconductor characteristics may be maintained without being a conductor. The first connection portion and the second connection portion may have conductive characteristics by a conductive process of performing plasma treatment on a semiconductor material using, for example, the gate electrode 150 as a mask. The first connection portion and the second connection portion by the conductive process have excellent conductive characteristics and may serve as an electrode or a wiring.

The gate insulating layer 140 may be formed on the active layer 130. The gate insulating layer 140 may be formed on the entire surface of the first substrate 111, but the present disclosure is not limited thereto, and a partial region of the gate insulating layer 140 may be patterned so that one end and another end of the gate insulating layer 140 correspond to one end and another end of the gate electrode 150, respectively.

The gate insulating layer 140 may include a silicon nitride film (SiNx) or a silicon oxide film (SiOx), but is not limited thereto. The gate insulating layer 140 may be formed of a single layer or a plurality of layers including an inorganic insulating material and/or an organic insulating material.

The gate electrode 150 may be formed on the gate insulating layer 140.

The gate electrode 150 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The gate electrode 150 may have a structure including one metal layer or a multilayer structure including at least two metal layers each having different physical properties.

The interlayer insulating layer 160 may be formed on the gate electrode 150. The interlayer insulating layer 160 insulates between the gate electrode 150 and the source electrode 171 and further insulates between the gate electrode 150 and the drain electrode 172. The interlayer insulating layer 160 may be formed of a single layer or a plurality of layers including an inorganic insulating material and/or an organic insulating material.

A contact hole may be formed in the interlayer insulating layer 160. Accordingly, a part of the upper surface of the first connection portion of the active layer 130 may be exposed by one contact hole, and further, a part of the upper surface of the second connection portion of the active layer 130 may be exposed by another contact hole.

The source electrode 171 and the drain electrode 172 may be disposed on the interlayer insulating layer 160.

The source electrode 171 may be electrically connected to the first connection portion of the active layer 130 by a contact hole, and the drain electrode 172 may be electrically connected to the second connection portion of the active layer 130 by a contact hole.

The source electrode 171 and the drain electrode 172 may be formed of the same material as the gate electrode 150, but are not limited thereto and may be formed of a material according to knowledge in the art.

The planarization layer 180 may be formed on the interlayer insulating layer 160, the source electrode 171, and the drain electrode 172. The planarization layer 180 may be formed on the source electrode 171 and the drain electrode 172 to planarize an upper surface of the planarization layer 180.

A contact hole is provided in the planarization layer 180, and a part of the upper surface of the drain electrode 172 may be exposed by the contact hole. However, in some cases, a part of the upper surface of the source electrode 171 may be exposed by the contact hole.

The planarization layer 180 may be formed of an organic insulating material. For example, the planarization layer 180 may be formed of an organic insulating material such as an acrylic resin, an epoxy resin, a phenolic resin, a polyamide resin, or a polyimide resin.

The first organic light emitting element EL1, the second organic light emitting element EL2, and the third organic light emitting element EL3 may be formed on the planarization layer 180. The first to third organic light emitting elements EL1 to EL3 may define a first light emitting area E1, a second light emitting area E2, and a third light emitting area E3, respectively.

The first organic light emitting element EL1, the second organic light emitting element EL2, and the third organic light emitting element EL3 may include first electrodes 190a, 190b, and 190c, light emitting layers 210a, 210b, and 210c, and the second electrodes 220a, 220b, and 220c, respectively, and the light emitting layers 210a, 210b, and 210c provided in each of the organic light emitting elements EL1, EL2, and EL3 may be partitioned by the bank 200.

The first electrodes 190a, 190b, and 190c may be formed on the planarization layer 180 and may be electrically connected to the drain electrode 172 (or the source electrode 171) through the contact hole provided in the planarization layer 180. The first electrodes 190a, 190b, and 190c may function as an anode.

The bank 200 may be formed on the first electrodes 190a, 190b, and 190c. In this case, a partial region of the upper surface of the first electrodes 190a, 190b, and 190c exposed without being covered by the bank 200 becomes a light emitting area. Accordingly, in the first light emitting element EL1, a partial region of the upper surface of the first electrode 190a exposed without being covered by the bank 200 becomes the first light emitting area E1, and in the second light emitting element EL2, a partial region of the upper surface of the first electrode 190b exposed without being covered by the bank 200 becomes the second light emitting area E2, and in the third light emitting element EL3, a partial region of the upper surface of the first electrode 190c exposed without being covered by the bank 200 may become the third light emitting area E3.

The bank 200 may be formed of an organic layer such as an acrylic resin, an epoxy resin, a phenolic resin, a polyamide resin, a polyimide resin, or the like.

The organic light emitting layers 210a, 210b, and 210c may be formed on the first electrodes 190a, 190b, and 190c. The organic light emitting layers 210a, 210b, and 210c may include any one of red, green, and blue light emitting layers patterned for each pixel, or may include a white light emitting layer connected to all of the pixels. When the organic light emitting layers 210a, 210b, and 210c include a white light emitting layer, for example, the organic light emitting layers 210a, 210b, and 210c may include a first stack including a blue light emitting layer, a second stack including a yellow-green light emitting layer, and a charge generation layer provided between the first stack and the second stack, but are not limited thereto.

The second electrode 220 may be formed on the organic light emitting layers 210a, 210b, and 210c. The second electrode 220 may function as a cathode.

The second electrode 220 may be formed on the entire surface of the bank 200 and the organic light emitting layers 210a, 210b, and 210c, for example.

The encapsulation layer 230 may include, for example, a first encapsulation layer 230a, a second encapsulation layer 230b, and a third encapsulation layer 230c. The first encapsulation layer 230a to the third encapsulation layer 230c may be sequentially stacked on the second electrode 220, the first encapsulation layer 230a and the third encapsulation layer 230c may be formed of an inorganic film layer including an inorganic material, and the second encapsulation layer 230b may be formed of an organic film layer including an organic material.

The first encapsulation layer 230a is formed at the lowermost end of the encapsulation layer 230 to be in contact with the upper surface of the second electrode 220. The first encapsulation layer 230a may be formed of a material such as silicon nitride (SiNx), silicon oxide (SiOx), silicon oxynitride (SiON), aluminum oxide (Al2O3), or the like.

The second encapsulation layer 230b may be formed on the first encapsulation layer 230a. The second encapsulation layer 230b may be formed of a material such as an acrylic resin, an epoxy resin, polyimide, polyethylene (PE), or silicon oxycarbon (SiOC).

The third encapsulation layer 230c may be formed on the second encapsulation layer 230b. The third encapsulation layer 230c may be formed of the same material as the first encapsulation layer 230a.

The touch electrode 240 may be formed on the encapsulation layer 230. More specifically, it may be formed on the third encapsulation layer 230c. Meanwhile, although not shown in detail, a separate insulating layer may be additionally provided between the encapsulation layer 230 and the touch electrode 240. The touch electrode 240 may sense touch input information by a self-capacitance method or touch input information by a mutual-capacitance method, but the present disclosure is not limited thereto.

The touch insulating layer 250 is formed on the touch electrode 240. The touch insulating layer 250 is formed on the touch electrode 240 to prevent or at least reduce moisture or oxygen from flowing into the touch electrode 240 from the outside.

Meanwhile, the touch electrode 240 and the touch insulating layer 250 may be omitted in some cases.

The color filters 260a, 260b, and 260c and the black matrix 270 may be formed on the touch insulating layer 250. Meanwhile, when the touch electrode 240 and the touch insulating layer 250 are omitted, the color filters 260a, 260b, and 260c and the black matrix 270 may be formed on the encapsulation layer 230.

The color filters 260a, 260b, and 260c may include a first color filter 260a, a second color filter 260b, and a third color filter 260c. The color filters 260a, 260b, and 260c may correspond to the light emitting areas E1, E2, and E3. For example, while overlapping the first light emitting element EL1, the first color filter 260a may transmit the light emitted from the first light emitting area E1 of the first light emitting element EL1, for example, the light of red (R). While overlapping the second light emitting element EL2, the second color filter 260b may transmit the light emitted from the second light emitting area E2 of the second light emitting element EL2, for example, the light of green (G). Furthermore, while overlapping the third light emitting element EL3, the third color filter 260c may transmit the light emitted from the third light emitting area E3 of the third light emitting element EL3, for example, the light of blue (B).

The black matrix 270 may be formed between the color filters 260a, 260b and 260c. The black matrix 270 is provided to cover a portion of upper surfaces of the color filters 260a, 260b, and 260c and to cover side surfaces of the color filters 260a, 260b and 260c.

The black matrix 270 may include a first portion 271 in contact with the side surfaces of the color filters 260a, 260b, and 260c, and a second portion 272 provided on the first portion 271 and in contact with portions of the upper surfaces of the color filters 260a, 260b, and 260c.

The second portion 272 protrudes compared to the first portion 271, and the thickness of the second portion 272 is formed to be thinner than the thickness of the first portion 271. By forming in this way, a part of light may pass through the second portion 272, and another part of light may not pass through the first portion 271.

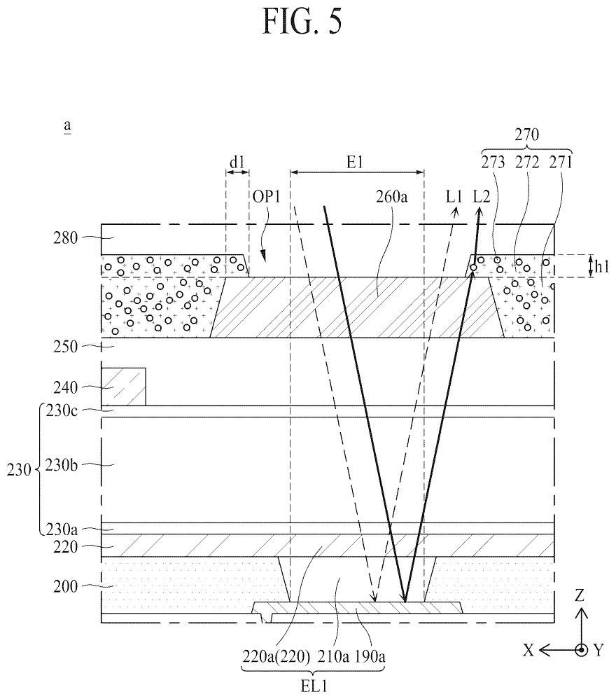

Furthermore, although not specifically illustrated, the first portion 271 and the second portion 272 of the black matrix 270 include a plurality of scattering particle (see 273 in FIG. 5) for scattering light. By forming in this way, the black matrix 270 may prevent or at least reduce the light emitted from the first light emitting area E1 and the second light emitting area E2 from being mixed while passing through the first color filter 260a and the second color filter 260b. Furthermore, it is possible to prevent or at least reduce a mura pattern from being formed while external light is introduced into the organic light emitting display device according to an embodiment of the present disclosure and is reflected by electrodes and wirings. Meanwhile, this will be described in more detail with reference to FIG. 5, which is an enlarged view of an area a to be described below.

The overcoating layer 280 may be formed on the color filters 260a, 260b and 260c and the black matrix 270.

Meanwhile, an optically clear adhesive member (OCA) may be formed on the color filters 260a, 260b, and 260c and the black matrix 270 and below the overcoating layer 280.

The second substrate 112 may be formed on the overcoating layer 280. The second substrate 112 may face the first substrate 111 and be combined.

The second substrate 112 may be made of glass or plastic. In particular, the second substrate 112 may be made of transparent plastic having flexible characteristics, for example, polyimide.

FIG. 5 is an enlarged view of a first pixel included in an organic light emitting display device according to an embodiment of the present disclosure. In this case, FIG. 5 corresponds to the area a of FIG. 4. In this case, in FIG. 5, the same reference numerals are assigned to the same elements as those shown in FIG. 4, and repeated descriptions will be omitted below.

As shown in FIG. 5, the black matrix 270 includes a first portion 271 provided to be in contact with the side surface of the first color filter 260a, a second portion 272 provided on the first portion 271 and covering a portion of the upper surface of the first color filter 260a, and scattering particles 273 provided in the first portion 271 and the second portion 272.

The first portion 271 may be thicker than the second portion 272 to prevent or at least reduce the light emitted from the first light emitting element EL1 from passing through the side surface of the first color filter 260a. By forming in this way, it is possible to prevent or at least reduce the light of different colors emitted from adjacent light emitting elements, for example, the first light emitting element EL1 and the second light emitting element EL2 of FIG. 4, from being mixed with each other. Meanwhile, FIG. 5 shows the scattering particles 273 provided in the first portion 271, but the present disclosure is not limited thereto, and the scattering particles 273 may not be formed in the first portion 271.

The first portion 271 may be in contact with a side surface of the first color filter 260a. Although not shown in detail, the first portion 271 may be provided to be in contact with at least one side surface of each of the color filters 260a, 260b, 260c and 260d.

The second portion 272 may be provided on the first portion 271 to be in contact with the first portion 271.

The second portion 272 may be formed to have a thinner thickness than the first portion 271. The second portion 272 may have a first thickness h1 in the third direction Z, and the first thickness h1 may range from 0.7 μm to 2 μm, and in one embodiment, the first thickness h1 may range from 0.7 μm to 1 μm. In this case, when the first thickness h1 of the second portion 272 is less than 0.7 μm, since the thickness of the black matrix 270 is reduced, the shielding function may be reduced, and accordingly, color mixing may be generated by light emitted from adjacent light emitting areas, and when the first thickness h1 of the second portion 272 exceeds 2 μm, the reflected external light may not be introduced into the second portion 272 and may not be scattered by the scattering particles 273.

One end of the second portion 272 may protrude by a first length d1 from one end of the first portion 271. In this case, the first length d1 by which the second portion 272 protrudes (which may also be referred to as the first length d1 of the second portion 272) may range from 1 μm to 4 μm, preferably from 1 μm to 2 μm. When the first length d1 of the second portion 272 is less than 1 μm, process control may be difficult, and when the first length d1 exceeds 4 μm, viewing angle characteristics of light emitted from the first light emitting area E1 may be deteriorated. One end of the second portion 272 is formed to protrude by a first length d1 from one end of the first portion 271, so that the second portion 272 may be in contact with an upper surface of the first color filter 260a. Although not specifically illustrated, the second portion 272 of the black matrix 270 may be provided to be in contact with an upper surface of at least one of the color filters 260a, 260b, 260c and 260d, respectively.

Since the scattering particles 273 are formed in the second portion 272 and the first thickness h1 of the second portion 272 is formed to have a thickness sufficient to transmit light, a path of the light passing through the second portion 272 of the external light reflected by being introduced into the organic light emitting display device according to an embodiment of the present disclosure may be partially changed. The scattering particles 273 may include at least one of TiO2, BaTiO3, ZrO2, SiO4, ZnO, SiO2, SiO, TiO2, ZrO2, and AlO4, and an average diameter of the scattering particles 273 may be less than 1 μm, but a material and a size of the scattering particles 273 are not limited thereto.

For example, when the first light L1 and the second light L2 flow in parallel from the outside into the organic light emitting display device according to an embodiment of the present disclosure, the first light L1 passes through the first color filter 260a and is reflected back to the outside, while the second light L2 is reflected by the first electrode 190a and passes through the second portion 272 covering a portion of the upper surface of the first color filter 260a. In this case, while the second light L2 is scattered by the scattering particles 273 provided in the second portion 272, the second light L2 has a different moving path from the first light L1.

According to an embodiment of the present disclosure, by varying the path of some of the light introduced from the outside by the second portion 272 of the black matrix 270, it is possible to prevent or at least reduce the formation of a Mura pattern, for example, a rainbow Mura, due to reinforcement interference of the first light L1 and the second light L2

Furthermore, the light passing through the second portion 272 of the external light flowing into the organic light emitting display device according to an embodiment of the present disclosure is scattered by the scattering particles 273 provided in the second portion 272 and the moving path of the light passing through the second portion 272 is different from the moving path of the light not passing through the second portion 272. In this case, similarly, the moving path of the light passing through the second portion 272 and the light not passing through the second portion 272 are different, so that a mura pattern due to reinforcement interference may be prevented from being formed. As a result, since the mura pattern formed by reflecting the external light is removed, the user's visibility may be improved.

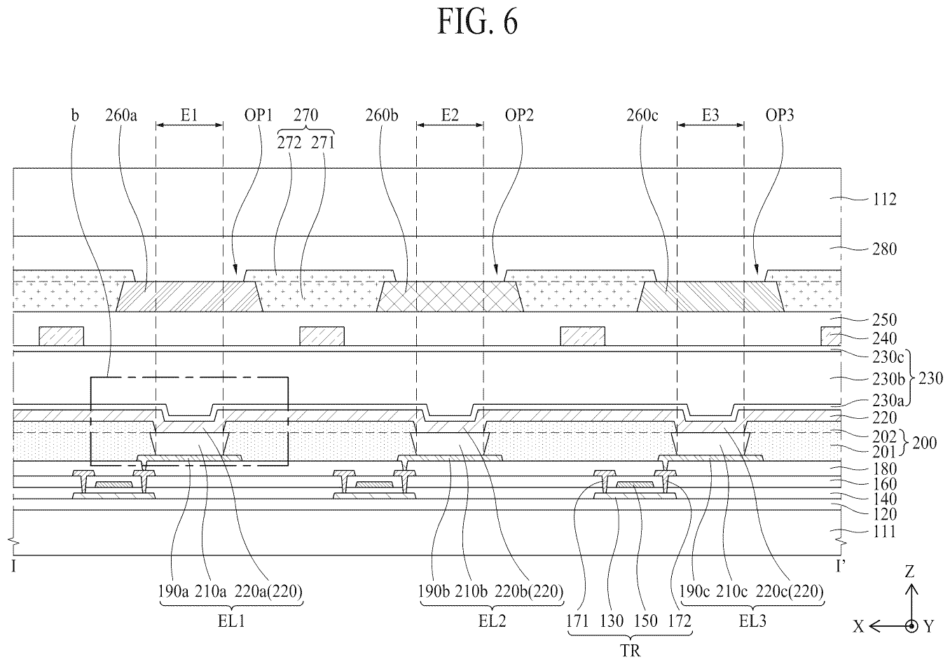

FIG. 6 is a cross-sectional view of pixels included in an organic light emitting display device according to another embodiment of the present disclosure. In this case, FIG. 6 corresponds to the cross-sectional I-I′ of FIG. 3. In this case, since an embodiment of FIG. 6 is the same as an embodiment of FIG. 4 except for a configuration of a bank, different configurations will be mainly described below.

As shown in FIG. 6, an organic light emitting display device according to another embodiment of the present disclosure includes a first substrate 111, a buffer layer 120, an active layer 130, a gate insulating layer 140, a gate electrode 150, an interlayer insulating layer 160, a source electrode 171, a drain electrode 172, a planarization layer 180, a first electrode 190a, 190b, and 190c, a bank 200, an organic light emitting layer 210a, 210b, and 210c, a second electrode 220, an encapsulation layer 230, a touch electrode 240, a touch insulating layer 250, color filters 260a, 260b, and 260c, a black matrix 270, an overcoating layer 280, and a second substrate 112.

The bank 200 includes a first portion 201 configured to divide the first light emitting element EL1, the second light emitting element EL2, and the third light emitting element EL3, and a second portion 202 provided on the first portion 201 and protruding from the first portion 201. In this case, the thickness of the second portion 202 is formed to be smaller than the thickness of the first portion 201.

According to another embodiment of the present disclosure, the bank 200 may include the same material as the black matrix 270. By forming in this way, a part of light may pass through the second portion 202, and a part of light may not pass through the first portion 201.

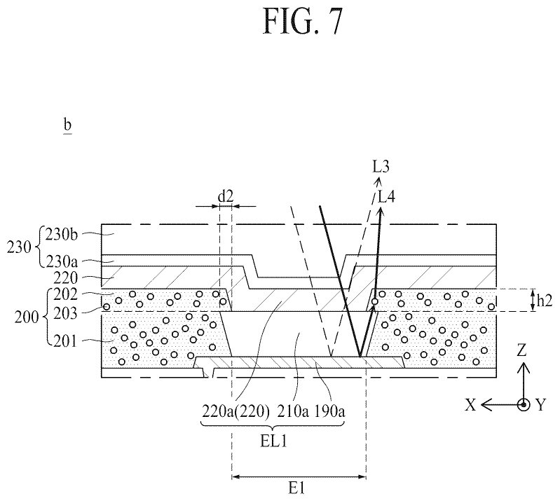

Furthermore, although not specifically illustrated, the first portion 201 and the second portion 202 of the bank 200 include scattering particles (see 203 in FIG. 7) that scatters light. By forming in this way, external light may be introduced into the organic light emitting display device according to another embodiment of the present disclosure and may prevent or at least reduce a mura pattern from being formed while being reflected by electrodes and wirings. Meanwhile, the description will be made in more detail with reference to FIG. 7, which is an enlarged view of region b to be described later.

FIG. 7 is an enlarged view of a first pixel included in an organic light emitting display device according to another embodiment of the present disclosure. In this case, FIG. 7 corresponds to the area b of FIG. 6. In this case, in FIG. 7, the same reference numerals are assigned to the same elements as those shown in FIG. 6, and repeated descriptions will be omitted below.

As shown in FIG. 7, the bank 200 includes a first portion 201 in contact with the organic light emitting layer 210a, a second portion 202 provided on the first portion 201 and covering a part of the upper surface of the organic light emitting layer 210a, and scattering particles 203 provided in the first portion 201 and the second portion 202.

The first portion 201 is formed to cover a portion of the first electrode 190a, thereby defining the first light emitting area E1. Specifically, a partial area of the upper surface of the first electrode 190a exposed without being covered by the first portion 201 may be defined as the first light emitting area E1. Meanwhile, FIG. 7 illustrates only a state in which the scattering particles 273 are formed in the first portion 201, but the present disclosure is not limited thereto, and the scattering particles 203 may not be formed in the first portion 201.

The second portion 202 may be formed to have a thinner thickness than the first portion 201. The second portion 202 may have a second thickness h2 in the third direction Z, and the second thickness h2 may range from 0.5 μm to 2 μm, in one embodiment from 0.5 μm to 0.7 μm. When the second thickness h2 is less than 0.5 μm, process control may be difficult to form the second portion 202, and when the second thickness h2 exceeds 2 μm, viewing angle characteristics of light emitted from the first light emitting area E1 may be deteriorated.

One end of the second portion 202 may protrude by a second length d2 from one end of the first portion 201. In this case, the second length d2 by which the second portion 202 protrudes (which may also be referred to as the second length d2 of the second portion 202) may range from 1 μm to 4 μm, in one embodiment from 1 μm to 2 μm. When the second length d2 of the second portion 202 is less than 1 μm, process control becomes difficult, a mura pattern may be visually recognized, and when the second length d2 exceeds 4 μm, luminance characteristics and viewing angle characteristics of light emitted from the first light emitting area E1 may be deteriorated.

Since the scattering particles 203 are formed in the second portion 202, and the first thickness h1 of the second portion 202 is formed to have a thickness sufficient to transmit light, a path of the light passing through the second portion 202 of the external light reflected by being introduced into the organic light emitting display device according to an embodiment of the present disclosure may be partially changed. The scattering particles 203 may include at least one of TiO2, BaTiO3, ZrO2, SiO4, ZnO, SiO2, SiO, TiO2, ZrO2, and AlO4, and an average diameter of the scattering particles 203 may be less than 1 μm, but a material and a size of the scattering particles 203 are not limited thereto.

For example, when the third light L3 and the fourth light L4 are introduced in parallel from the outside into the organic light emitting display device according to another embodiment of the present disclosure, the third light L3 is reflected through the first electrode 190a to escape to the outside again, while the fourth light L4 is reflected by the first electrode 190a and passes through the second portion 202. In this case, while the fourth light L4 is scattered by the scattering particles 203 provided in the second portion 202, the fourth light L4 has a moving path different from that of the third light L3.

According to another embodiment of the present disclosure, by varying the path of some of the light introduced from the outside by the second portion 202 of the bank 200, it is possible to prevent or at least reduce the formation of a Mura pattern, for example, a rainbow Mura, caused by reinforcement interference of the third light L3 and the fourth light L4.

Furthermore, the light passing through the second portion 202 of the external light flowing into the organic light emitting display device according to an embodiment of the present disclosure is scattered by the scattering particles 203 provided in the second portion 202 and for such external light, the moving path of the light passing through the second portion 202 is different from the moving path of the light not passing through the second portion 202. In this case, similarly, the moving path of the light passing through the second portion 202 and the light not passing through the second portion 202 are different, so that a mura pattern caused by reinforcement interference may be prevented from being formed. As a result, since the mura pattern formed by reflecting the external light is removed, the user's visibility may be improved.

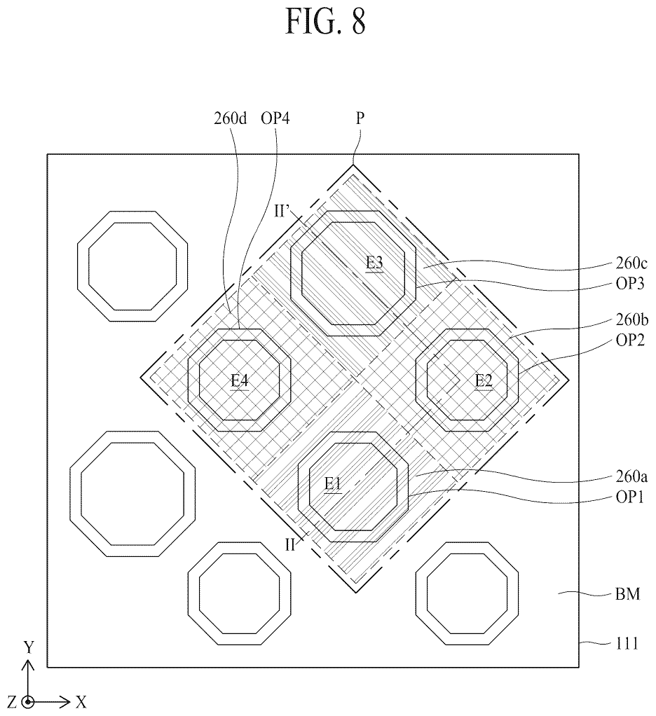

FIG. 8 is a plan view illustrating an example of pixels included in an organic light emitting display device according to another embodiment of the present disclosure. Meanwhile, since an embodiment of FIG. 8 is the same as an embodiment of FIG. 3 except for a color filter, different configurations will be mainly described below.

As shown in FIG. 8, an organic light emitting display device according to another embodiment of the present disclosure includes a plurality of pixels P, a color filter 260, and a black matrix BM having an opening OP.

The color filters 260a, 260b, 260c, and 260d include a first color filter 260a, a second color filter 260b, a third color filter 260c, and a fourth color filter 260d. The color filters 260a, 260b, 260c, and 260d may transmit light of the same wavelength band as the color of the light emitted from the light emitting areas E1, E2, E3, and E4. For example, the first color filter 260a is provided to correspond to the first light emitting area E1 and may transmit red (R) light, the second color filter 260b and the fourth color filter 260d are provided to correspond to the second light emitting area E2 and the fourth light emitting area E4, respectively, and may transmit green (G) light, and the third color filter 260c is provided to correspond to the third light emitting area E3, and may transmit blue (B) light.

Unlike the embodiment of FIG. 3, the color filters 260a, 260b, 260c, and 260d may be formed in a different shape from the light emitting areas E1, E2, E3, and E4. For example, the light emitting areas E1, E2, E3, and E4 are provided in an octagonal shape, while the color filters 260a, 260b, 260c, and 260d may be divided into tetragonal shapes. Meanwhile, the present disclosure is not limited thereto.

In addition, each of the color filters 260a, 260b, 260c, and 260d may be continuously formed without being spaced apart from each other.

Meanwhile, in FIG. 8, only color filters 260a, 260b, 260c, and 260d are formed on the light emitting areas E1, E2, E3, and E4 provided in the pixel P, and the same color filters as those of color filters 260a, 260b, 260c, and 260d provided in the pixel P are formed in other light emitting areas shown in FIG. 8.

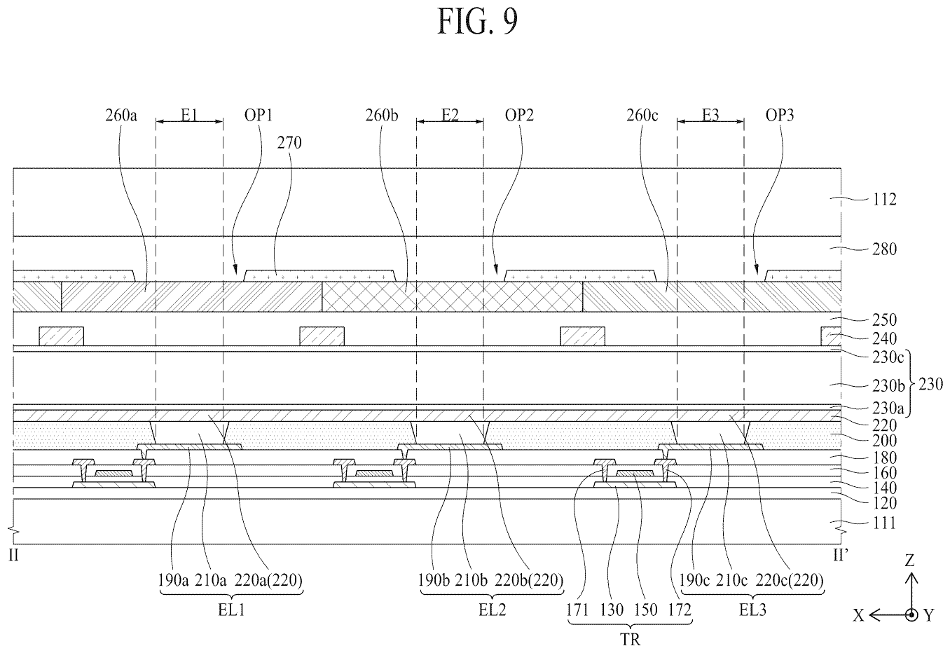

FIG. 9 is a cross-sectional view of pixels included in an organic light emitting display device according to another embodiment of the present disclosure. In this case, FIG. 9 corresponds to the cross-sectional II-II′ of FIG. 8. Meanwhile, an embodiment of FIG. 9 is the same as an embodiment of FIG. 4 except for the configuration of the color filter and the black matrix, and thus different configurations will be mainly described below.

As shown in FIG. 9, an organic light emitting display device according to another embodiment of the present disclosure includes a first substrate 111, a buffer layer 120, an active layer 130, a gate insulating layer 140, a gate electrode 150, an interlayer insulating layer 160, a source electrode 171, a drain electrode 172, a planarization layer 180, first electrodes 190a, 190b, and 190c, a bank 200, organic light emitting layers 210a, 210b, and 210c, a second electrode 220a, 220b, 220c, an encapsulation layer 230, a touch electrode 240, a touch insulating layer 250, color filters 260a, 260b, and 260c, a black matrix 270, an overcoating layer 280, and a second substrate 112.

According to another embodiment of the present disclosure, color filters 260a, 260b and 260c may be formed on the touch insulating layer 250. Meanwhile, when the touch electrode 240 and the touch insulating layer 250 are omitted, color filters 260a, 260b and 260c may be formed on the encapsulation layer 230.

The color filters 260a, 260b, and 260c include a first color filter 260a, a second color filter 260b, and a third color filter 260c. The color filters 260a, 260b, and 260c may correspond to the light emitting areas E1, E2, and E3. For example, while overlapping the first light emitting element EL1, the first color filter 260a may transmit the light emitted from the first light emitting area E1 of the first light emitting element EL1, for example, the light of red (R). While overlapping the second light emitting element EL2, the second color filter 260b may transmit the light emitted from the second light emitting area E2 of the second light emitting element EL2, for example, the light of green (G). Furthermore, while overlapping the third light emitting element EL3, the third color filter 260c may transmit the light emitted from the third light emitting area E3 of the third light emitting element EL3, for example, the light of blue (B).

The color filters 260a, 260b, and 260c may be provided to be in contact with each other. For example, the first color filter 260a and the second color filter 260b may be in contact with each other in a region in which the bank 200 that divides the first light emitting area E1 and the second light emitting area E2 is formed. Accordingly, one side of the first color filter 260a, for example, a right side, may be in contact with one side of the second color filter 260b, for example, a left side, and the second color filter 260b and the third color filter 260c may be in contact with each other in a region in which the bank 200 that divides the second light emitting area E2 and the third light emitting area E3 is formed.

The black matrix 270 may be formed on the color filters 260a, 260b, and 260c. Specifically, the black matrix 270 may be provided to be in contact with portions of upper surfaces of the color filters 260a, 260b, and 260c. For example, the black matrix 270 may be provided between the first light emitting area E1 and the second light emitting area E2 to cover a portion of the upper surface of the first color filter 260a and a portion of the upper surface of the second color filter 260b, and the black matrix 270 may be provided between the second light emitting area E2 and the third light emitting area E3 to cover a portion of the upper surface of the second color filter 260b and a portion of the upper surface of the third color filter 260c.

Meanwhile, although not specifically illustrated, the black matrix 270 includes scattering particles (see 273 of FIG. 5) configured to scatter light. By forming in this way, the black matrix 270 may prevent external light from being introduced into the organic light emitting display device according to another embodiment of the present disclosure and reflected by electrodes and wirings. Therefore, it is possible to prevent or at least reduce the formation of the mura pattern. Meanwhile, the principle of preventing the formation of the Mura pattern has been described in detail with reference to FIG. 5, and thus detailed descriptions thereof will be omitted.

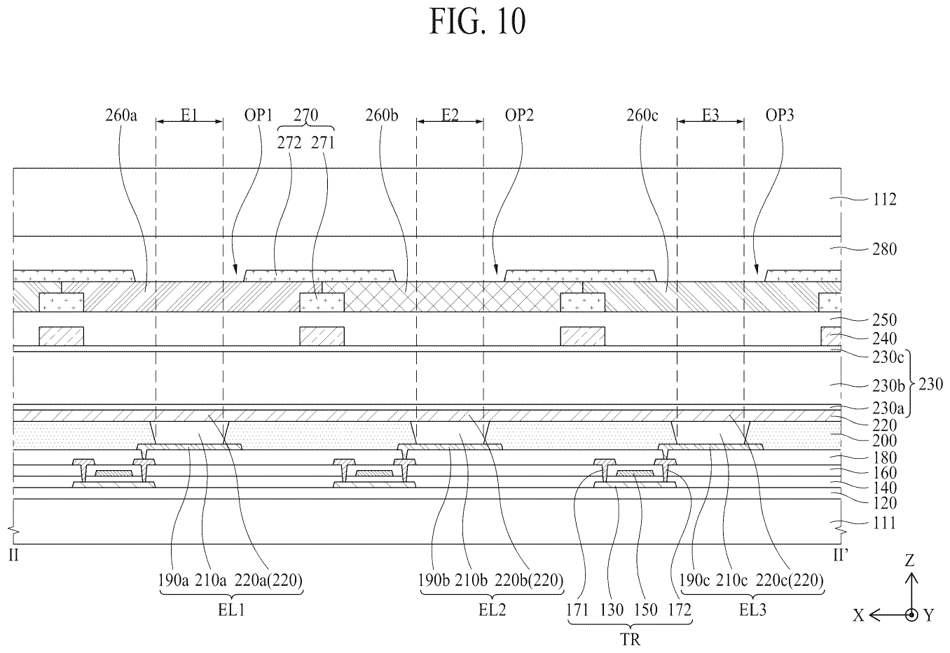

FIG. 10 is a cross-sectional view of pixels included in an organic light emitting display device according to another embodiment of the present disclosure. In this case, FIG. 10 corresponds to the cross-sectional II-II′ of FIG. 8. Meanwhile, an embodiment of FIG. 10 is the same as an embodiment of FIG. 9 except for the configuration of the black matrix, and thus different configurations will be mainly described below.

As shown in FIG. 10, an organic light emitting display device according to another embodiment of the present disclosure includes a first substrate 111, a buffer layer 120, an active layer 130, a gate insulating layer 140, a gate electrode 150, an interlayer insulating layer 160, a source electrode 171, a drain electrode 172, a planarization layer 180, first electrodes 190a, 190b, and 190c, a bank 200, organic light emitting layers 210a, 210b, and 210c, a second electrode 220a, 220b, 220c, an encapsulation layer 230, a touch electrode 240, a touch insulating layer 250, color filters 260a, 260b, and 260c, a black matrix 270, an overcoating layer 280, and a second substrate 112.

The black matrix 270 according to another embodiment of the present disclosure includes a first portion 271 and a second portion 272. Unlike the embodiment of FIG. 4, the first portion 271 and the second portion 272 may be spaced apart from each other without being in contact with each other.

In this case, the first portion 271 is provided between the color filters 260a, 260b, and 260c to partition the color filters 260a, 260b, and 260c, and the second portion 272 is provided on the color filters 260a, 260b, and 260c to prevent the formation of a mura pattern as external light is introduced and reflected.

Each of the color filters 260a, 260b, 260c, and 260d may be provided to be in contact with each other without being spaced apart from each other, and further, each of the color filters 260a, 260b, 260c, and 260d may be in contact with each other in an area overlapping the black matrix 270. For example, a side surface of the first color filter 260a and a side surface of the second color filter 260b may be in contact with each other between the first portion 271 and the second portion 272.

The first portion 271 of the black matrix 270 may be provided at the boundary between the color filters 260a, 260b, and 260c. For example, the first portion 271 may be provided at an area where the first color filter 260a and the second color filter 260b are in contact with each other, and the first portion 271 may be provided at an area where the second color filter 260b and the third color filter 260c are in contact with each other. As the first portion 271 is formed in this way, light passing through the adjacent color filters 260a, 260b, and 260c may be prevented from being mixed with each other.

Meanwhile, although not specifically illustrated, the first portion 271 may include scattering particles (see 273 of FIG. 5) for scattering light.

The second portion 272 of the black matrix 270 is formed on the color filters 260a, 260b, and 260c. Specifically, the second portion 272 may be provided to be in contact with portions of the upper surfaces of the color filters 260a, 260b, and 260c. For example, the second portion 272 may be provided between the first light emitting area E1 and the second light emitting area E2 to cover a portion of the upper surface of the first color filter 260a and a portion of the upper surface of the second color filter 260b, and the second portion 272 may be provided between the second light emitting area E2 and the third light emitting area E3 to cover a portion of the upper surface of the second color filter 260b and a portion of the upper surface of the third color filter 260c.

Meanwhile, although not specifically illustrated, the second portion 272 of the black matrix 270 includes scattering particles (see 273 of FIG. 5) configured to scatter light. By forming in this way, the second portion 272 of the black matrix 270 may prevent external light from being introduced into the organic light emitting display device according to another embodiment of the present disclosure and reflected by electrodes and wirings. Therefore, it is possible to prevent or at least reduce the formation of the mura pattern. Meanwhile, the principle of preventing the formation of the Mura pattern has been described in detail with reference to FIG. 5, and thus detailed descriptions thereof will be omitted.

Accordingly, the present disclosure may have the following advantages.

According to an embodiment of the present disclosure, the black matrix includes a first portion with thickness which the light does not transmit and a second portion formed on the first portion to have a thickness through which light can be transmitted and including scattering particles that scatter light, thereby preventing or at least reducing the light transmitted through the color filter from being mixed and preventing or at least reducing the formation of a mura pattern as external light introduced into the organic light emitting display device is reflected by electrodes and wirings.

According to an embodiment of the present disclosure, by forming a plurality of light emitting areas and a black matrix opening provided to correspond to the light emitting area in an n-gon (n is an integer of 6 or more), a circular shape, or an elliptical shape and maintaining a constant distance from one side of the light emitting area to any one side of the black matrix opening, a mura pattern may be prevented from being formed by reflecting external light introduced into the organic light emitting display device by electrodes and wires.

According to an embodiment of the present disclosure, since the formation of the mura pattern by external light reflected by the electrode and the wiring by being introduced into the organic light emitting display device is prevented or minimized, the user's visibility may be improved.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. An organic light emitting display device comprising:
a substrate;
a first light emitting area on the substrate, the first light emitting area emitting light of a first color;
a second light emitting area on the substrate, the second light emitting area emitting light of a second color that is different from the first color;
a first color filter on the first light emitting area;
a second color filter on the second light emitting area; and
a black matrix in contact with at least one of an upper surface of the first color filter and an upper surface of the second color filter, the black matrix including scattering particles.

2. The organic light emitting display device according to claim 1, wherein the black matrix includes a first portion between the first color filter and the second color filter, and a second portion on the first portion,
wherein one end of the second portion protrudes by a first length from one end of the first portion.

3. The organic light emitting display device according to claim 2, wherein a thickness of the first portion is greater than a thickness of the second portion.

4. The organic light emitting display device according to claim 3, wherein the first portion does not pass a light emitted from any one of the first light emitting area and the second light emitting area, and the second portion passes the light emitted from any one of the first light emitting area and the second light emitting area.

5. The organic light emitting display device according to claim 2, wherein the first portion and the second portion are in contact with each other.

6. The organic light emitting display device according to claim 2, wherein the second portion is in contact with at least one of the upper surface of the first color filter and the upper surface of the second color filter.

7. The organic light emitting display device according to claim 2, wherein the first portion is in contact with at least one of a side surface of the first color filter and a side surface of the second color filter.

8. The organic light emitting display device according to claim 2, wherein a thickness of the second portion is greater than or equal to 0.7 μm and less than or equal to 2 μm.

9. The organic light emitting display device according to claim 2, wherein a first length by which the second portion protrudes is greater than or equal to 1 μm and less than or equal to 4 μm.

10. The organic light emitting display device according to claim 2, wherein the first portion and the second portion are not in contact with each other, and a side surface of the first color filter and a side surface of the second color filter are in contact between the first portion and the second portion of the black matrix.

11. The organic light emitting display device according to claim 1, wherein a side surface of the first color filter and a side surface of the second color filter are in contact with each other, and the side surface where the first color filter and the second color filter contact each other overlaps the black matrix.

12. The organic light emitting display device according to claim 1, further comprising:
a bank that partitions the first light emitting area and the second light emitting area, the bank including scattering particles.

13. The organic light emitting display device according to claim 12, wherein the bank includes a first portion between the first light emitting area and the second light emitting area, and a second portion on the first portion, and one end of the second portion of the bank protrudes by a second length from one end of the first portion of the bank.

14. The organic light emitting display device according to claim 13, wherein a thickness of the second portion of the bank is greater than or equal to 0.7 μm and less than or equal to 2 μm.

15. The organic light emitting display device according to claim 13, wherein a first length by which the second portion of the bank protrudes is greater than or equal to 1 μm and less than or equal to 4 μm.

16. The organic light emitting display device according to claim 1, wherein the first color filter and the first light emitting area have different shapes, and/or the first color filter and the second color filter are continuously formed without being spaced apart from each other.

17. An organic light emitting display device comprising:
a substrate including a first light emitting area and a second light emitting area;
a first color filter on the first light emitting area;
a second color filter on the second light emitting area; and
a black matrix on the first color filter and the second color filter,
wherein the black matrix includes a first opening corresponding to the first light emitting area and a second opening corresponding to the second light emitting area, the black matrix including scattering particles.

18. The organic light emitting display device according to claim 17, wherein the first color filter and the second color filter are spaced apart from each other by the black matrix.

19. The organic light emitting display device according to claim 17, wherein the first color filter and the second color filter are in contact with each other.

20. The organic light emitting display device according to claim 17, wherein an upper surface of any one of the first color filter and the second color filter is covered by the black matrix.

21. The organic light emitting display device according to claim 17, wherein the first light emitting area and the second light emitting area are disposed in a first n-gon shape where n is an integer of 6 or more,
and the first opening and the second opening are disposed in a second n-gon wherein n is an integer of 6 or more.

22. The organic light emitting display device according to claim 21, wherein the first color filter and the second color filter are disposed in a third n-gon shape where n is an integer of 6 or more.

23. The organic light emitting display device according to claim 20, wherein the first light emitting area has a first side and a second side,
wherein the first opening has a third side facing the first side and a fourth side facing the second side,
wherein a distance between the first side and the third side and a distance between the second side and the fourth side are a same.

24. The organic light emitting display device according to claim 17, wherein the first color filter and the first light emitting area have different shapes, and/or the first color filter and the second color filter are continuously formed without being spaced apart from each other.

25. The organic light emitting display device according to claim 17, further comprising:
a bank for partitioning the first light emitting area and the second light emitting area,
wherein the bank includes scattering particles.
